(19) United States
(12) Patent Application Publication
(10) Pub. No.: US 2025/0349493 A1
(43) Pub. Date: Nov. 13, 2025

(54) ELECTRON MICROSCOPE AND IMAGE CAPTURING METHOD THEREOF

(71) Applicant: Hitachi High-Tech Corporation, Minato-ku, Tokyo (JP)

(72) Inventors: Hideo MORISHITA, Tokyo (JP); Takashi OHSHIMA, Tokyo (JP); Tatsuro IDE, Tokyo (JP); Yoichi OSE, Tokyo (JP); Daichi TAKANE, Tokyo (JP)

(21) Appl. No.: 18/864,649

(22) PCT Filed: Jun. 20, 2022
(86) PCT No.: PCT/JP2022/024470

§ 371 Date: Nov. 11, 2024

(51) Int. Cl. H01J 37/073; H01J 37/147; H01J 37/18; H01J 37/28

(52) U.S. Cl. CPC H01J 37/073; H01J 37/1472; H01J 37/18; H01J 37/28; H01J 2237/04735; H01J 2237/188; H01J 2237/2803

(57) ABSTRACT

In an axisymmetric electron gun structure, a part of gas molecules flowing from a vacuum chamber having relatively low vacuum reach a photoelectric film, causing problems of deterioration of an NEA surface, instability of an emission current, and a reduction in life of the photoelectric film. An electron microscope including an excitation light source; a photoelectric film formed on a transparent substrate; a condensing lens configured to condense excitation light to the photoelectric film; an anode electrode configured to accelerate an electron beam that is generated when the excitation light is condensed and irradiated to the photoelectric film; a first differential exhaust diaphragm provided close to the photoelectric film and having a passage hole off an axis; a second differential exhaust diaphragm provided close to a sample and having a passage hole on an optical axis; and a deflector for trajectory control of the electron beam.

### TECHNICAL FIELD

The present invention relates to an electron microscope as an electron beam application apparatus equipped with an electron gun using a photoelectric film, and an image capturing method thereof.

### BACKGROUND ART

Surface morphology and composition distribution of a sample can be measured by using a scanning electron microscope (SEM) that irradiates and scans the sample with a focused electron beam (the electron beam can be referred to as a beam of electrons), detects electrons emitted, and displays a signal intensity at each irradiation point. In order to obtain high spatial resolution in the SEM, a high-luminance electron source is required. As a high-luminance electron source for the SEM, a field emission (FE) electron source using electrons emitted by applying a strong electric field to a tip of a needle-like electrode is widely used. On the other hand, in recent years, in an electron source using a photoelectric film whose surface exhibits negative electron affinity (NEA), high luminance (about 1×10⁷ A/m²/sr/V) similar to that of a Schottky FE electron source has been reported (PTL 1).

Since energy spread of an electron beam emitted from the electron source using the photoelectric film having the high-luminance NEA surface is smaller than that of a cold cathode type FE electron source, a feature is presented that high observation performance can be obtained particularly under an irradiation condition of energy of about 1 keV or less, which is advantageous for observation of a sample electrode surface.

### CITATION LIST

### Patent Literature

PTL 1: WO2021/192070

### SUMMARY OF INVENTION

### Technical Problem

When cesium or oxygen is adsorbed on a surface of a photoelectric film made of p-type gallium arsenide (GaAs) having a high impurity concentration and the work function is reduced, an NEA surface is obtained where a vacuum level is lower than an energy level at a lower end of a conduction band of the photoelectric film, and when light is irradiated onto this surface, electrons excited within the photoelectric film are efficiently emitted. In particular, since an angular range of the electrons emitted from the NEA surface of the photoelectric film made of p-type GaAs is as small as about 10 degrees or less depending on, for example, an effective mass of the electrons in GaAs, high-luminance characteristics similar to those of the Schottky FE electron source can be obtained by condensing the excitation light to reduce an electron emission region to about φ 1 μm and point source the electron emission region. In order to stably use the electron beam emitted from the NEA surface, it is necessary to maintain extreme high vacuum (typically, 10-8 Pa or below) around the photoelectric film. Therefore, an electron gun using the NEA surface of the photoelectric film made of p-type GaAs has a multi-stage differential exhaust structure, and the emitted electron beam passes through a diaphragm provided between differential exhaust chambers so that a trajectory thereof is adjusted. Accordingly, the electron beam emitted from the NEA surface can be used as a probe of an electron microscope.

When a housing of an electron microscope has an axisymmetric structure, electron beam passage holes of differential exhaust diaphragms provided on the path of the electron beam serving as a probe are all provided at axisymmetric positions, and a path through which gas molecules can pass without being shielded exists between the sample and the electron source. In this case, the gas molecules flow into an electron gun chamber from a sample chamber having a relatively low degree of vacuum. When the gas molecules reach the vicinity of an electron emission portion of the photoelectric film, the NEA surface deteriorates due to gas adsorption to the photoelectric film. In particular, under an emission condition in which an emission current is large, the NEA surface deteriorates due to a mechanism called ion feedback in which electrons emitted from the photoelectric film collide with the gas molecules, and the gas molecules are ionized and accelerated to collide with the photoelectric film. As described above, in the electron source using the photoelectric film in which an active layer is formed of p-type GaAs, there are problems such as deterioration of luminance characteristics due to gas molecules, instability of the emission current, and a reduction in life of the NEA surface.

### Solution to Problem

An electron microscope according to an embodiment of the invention includes: an excitation light source configured to generate excitation light; a photoelectric film (photocathode) formed on a transparent substrate; a condensing lens configured to condense the excitation light toward the photoelectric film; an anode electrode provided facing the photoelectric film and configured to accelerate an electron beam, the electron beam being generated from the photoelectric film when the excitation light condensed by the condensing lens is incident through the transparent substrate of the photoelectric film; a first differential exhaust diaphragm provided close to the photoelectric film and having a first passage hole; a second differential exhaust diaphragm provided closer to a sample with respect to the first differential exhaust diaphragm and having a second passage hole provided axisymmetrically with respect to an electron optical system; and a deflector provided between the first differential exhaust diaphragm and the second differential exhaust diaphragm and configured to adjust a trajectory of the electron beam. The first passage hole of the first differential exhaust diaphragm is provided non-axisymmetrically with respect to an electron optical system.

The electron beam generated by irradiating the excitation light off an axis of the anode electrode facing the photoelectric film is converged by an electrostatic lens action formed in a gap between the photoelectric film and the anode electrode and is then deflected in a direction away from the axis of the anode electrode. The deflected electron beam is passed through the first passage hole of the first differential exhaust diaphragm that is provided non-axisymmetrically off an optical axis, and the electron beam that is returned again and passes through the second passage hole of the second differential exhaust diaphragm provided axisymmetrically is used as a probe of the electron microscope.

### Advantageous Effects of Invention

According to the electron gun structure described above, gas molecules flowing into an electron gun chamber from a vacuum chamber having a relatively low degree of vacuum can be prevented from reaching an electron emission portion of the photoelectric film, without impairing useful features in obtaining high spatial resolution in the electron microscope, such as high luminance characteristics and monochromaticity of an electron source in which a photoelectric film formed of p-type GaA having an NEA surface is used. Accordingly, deterioration of luminance characteristics due to adsorption of the gas molecules to the surface of the photoelectric film and ion feedback is alleviated and an emission current is stabilized, and the life of the NEA surface can be lengthened. Further, the electron source using a photoelectric film having an NEA surface can be mounted and used in an electron microscope that is used in a low vacuum environment in which the pressure around a sample is about 100 Pa. The details will be described in the following embodiments.

### BRIEF DESCRIPTION OF DRAWINGS

FIG. 1 is a diagram illustrating a schematic configuration example of an electron gun according to a first embodiment.

FIG. 2 is a diagram illustrating a schematic configuration example of an electron gun according to a comparative example.

FIG. 3 is a diagram illustrating a schematic configuration example and electric potential distribution of the electron gun according to the first embodiment.

FIG. 4 is a diagram illustrating a schematic configuration of a scanning electron microscope according to the first embodiment.

FIG. 5 is a graph illustrating variation over time of a cathode voltage according to the first embodiment.

FIG. 6 is a diagram schematically illustrating an electron beam control method according to the first embodiment.

FIG. 7A is a diagram illustrating a first configuration example of a first differential exhaust diaphragm according to the first embodiment.

FIG. 7B is a diagram illustrating a second configuration example of the first differential exhaust diaphragm according to the first embodiment.

FIG. 7C is a diagram illustrating a third configuration example of the first differential exhaust diaphragm according to the first embodiment.

FIG. 8 is a graph illustrating a relationship between an off-axis amount of an excitation point and a deflection angle of an electron beam according to the first embodiment.

FIG. 9A is a diagram illustrating a fourth configuration example of the first differential exhaust diaphragm according to the first embodiment.

FIG. 9B is a diagram illustrating a fifth configuration example of the first differential exhaust diaphragm according to the first embodiment.

FIG. 9C is a diagram illustrating a sixth configuration example of the first differential exhaust diaphragm according to the first embodiment.

FIG. 10 is a diagram schematically illustrating an excitation optical system and an electron gun according to a second embodiment.

FIG. 11 is a diagram schematically illustrating an excitation optical system according to the third embodiment.

FIG. 12 is a diagram schematically illustrating an excitation optical system according to a fourth embodiment.

FIG. 13 is a flowchart illustrating an adjustment procedure of the electron gun according to the first embodiment.

FIG. 14 is a flowchart illustrating an adjustment procedure of the electron gun according to the first embodiment.

FIG. 15 is a diagram illustrating a passage hole of a differential exhaust diaphragm of the electron gun according to the first embodiment and a passage hole of a differential exhaust diaphragm of the electron gun according to the comparative embodiment.

FIG. 16 is a flowchart illustrating an image capturing method of the electron microscope according to the first embodiment.

### DESCRIPTION OF EMBODIMENTS

Hereinafter, embodiments of the invention will be described in detail with reference to the drawings.

### First Embodiment

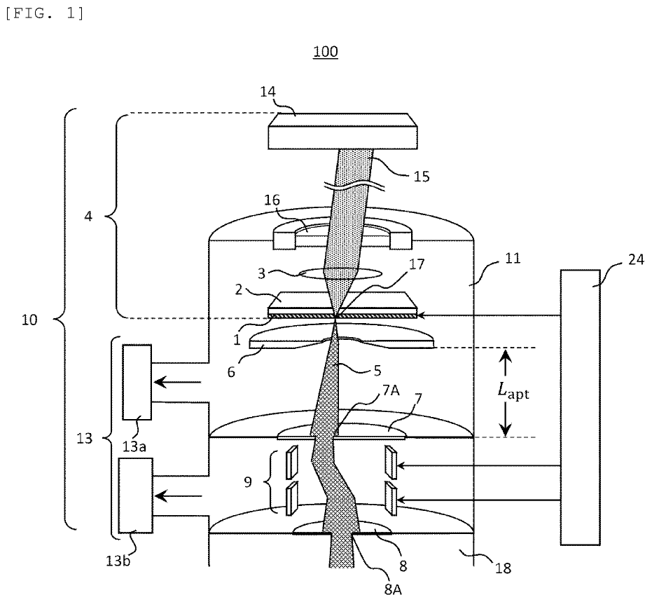

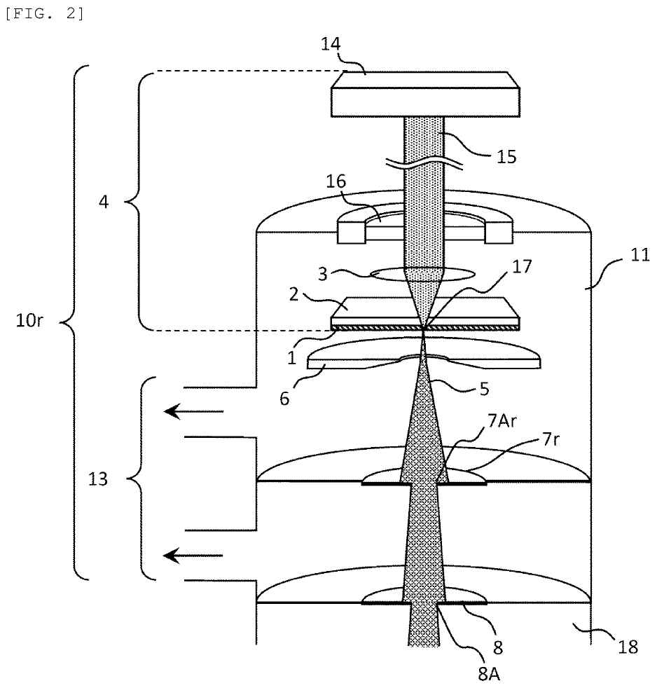

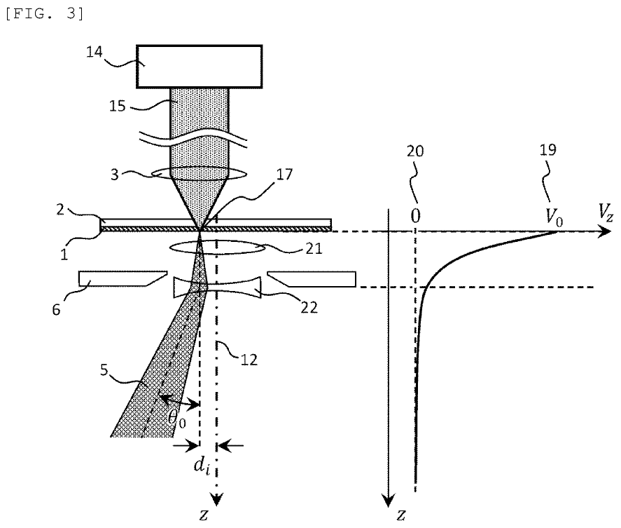

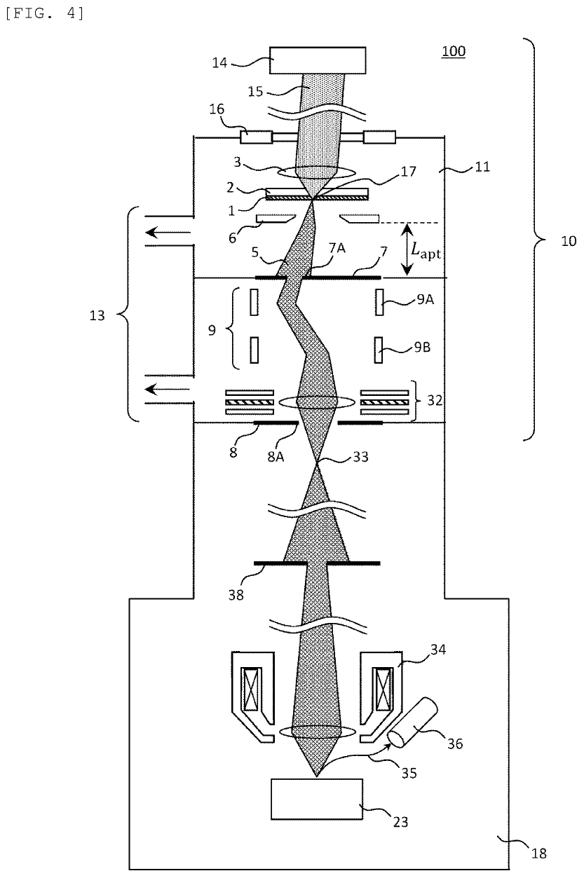

FIG. 1 is a diagram illustrating a schematic configuration example of an electron gun according to a first embodiment. FIG. 2 is a diagram illustrating a schematic configuration example of an electron gun according to a comparative embodiment. FIG. 3 is a diagram illustrating the schematic configuration example and electric potential distribution of the electron gun according to the first embodiment. FIG. 4 is a diagram illustrating a schematic configuration example of a scanning electron microscope according to the first embodiment. FIG. is a diagram illustrating a passage hole of a differential exhaust diaphragm of the electron gun according to the embodiment and a passage hole of a differential exhaust diaphragm of the electron gun according to the comparative embodiment.

FIG. 1 illustrates an example of an electron gun structure according to an embodiment of the invention. FIG. 1 illustrates a configuration in which an electron gun 10 according to the embodiment is mounted on a scanning electron microscope 100. In the embodiment, a control method of a trajectory of an electron beam 5 emitted from a photoelectric film 1 will be mainly described, and a configuration and a mechanism of an excitation optical system will be described in detail in a second embodiment and subsequent embodiments. The electron beam 5 can be referred to as a beam of electrons. The photoelectric film 1 is a photoelectric film whose surface exhibits negative electron affinity (NEA).

In a configuration of a photocathode used in the embodiment, it is assumed that a semi-conductor photoelectric film (hereinafter referred to as a photoelectric film) 1 that emits electrons by excitation light irradiation is formed on a transparent substrate 2, and the photocathode is hereinafter referred to as the photoelectric film 1. The electron gun 10 of the embodiment includes the photoelectric film 1 formed on the transparent substrate 2, a condensing lens 3, an excitation optical system 4 (the excitation optical system 4 includes an excitation light source 14, a viewing port 16, the condensing lens 3, the transparent substrate 2, and the photoelectric film 1) that condenses and irradiates excitation light 15 of the excitation light source 14 to the photoelectric film 1, an anode electrode 6 that is provided facing a photocathode and accelerates the electron beam 5 generated from the photoelectric film 1, a first differential exhaust diaphragm 7 that is provided to maintain extreme high vacuum around the photoelectric film 1 and has a passage hole (first passage hole) 7A for the electron beam 5 at a non-axisymmetric position, a second differential exhaust diaphragm 8 that has a passage hole (second passage hole) 8A for the electron beam 5 at an axisymmetric position, a deflector 9, and a controller 24 serving as a control device.

The deflector 9 can be implemented in multiple stages, and is provided between the first differential exhaust diaphragm 7 and the second differential exhaust diaphragm 8. The deflector 9 is controlled by the controller 24 such that the electron beam 5 passing through the passage hole 7A of the first differential exhaust diaphragm 7 is returned to an optical axis of an electron optical system before passing through the second differential exhaust diaphragm 8 and the electron beam 5 passes through the passage hole 8A of the second differential exhaust diaphragm 8.

The axis or the optical axis is an expression based on the premise that the electron optical system in the electron microscope 100, such as an electrode for drawing out the electron beam 5 from the photoelectric film 1 and the lens 3 for condensing the electron beam 5, has an ideal axisymmetric structure. In an actual device configuration of the electron microscope 100, even if components are axisymmetric configurations, respective axes do not necessarily overlap on the same straight line for the sake of the processing accuracy and the assembling accuracy of parts and members. Therefore, it is necessary to perform axis adjustment for a specific component by appropriately controlling the trajectory of the irradiation electron beam 5 using various alignment means such as the deflector 9. An axis to be passed through each component will be appropriately explained in the description of the following embodiments.

FIG. 1 illustrates the electron gun 10 in which the photoelectric film 1 is provided. The electron gun 10 is installed in an electron gun chamber (also referred to as a vacuum chamber) 11, and an inside of the electron gun chamber 11 is maintained at extreme high vacuum by vacuum exhaust equipment 13. An ion pump, a non-evaporable getter pump (NEG), or the like is used as the vacuum exhaust equipment 13 for maintaining extreme high vacuum around the photoelectric film 1. The vacuum exhaust equipment 13 includes first vacuum exhaust equipment 13a and second vacuum exhaust equipment 13b. The photoelectric film 1 is provided in the vacuum chamber 11 together with the condensing lens 3, and the excitation light 15 emitted from the excitation light source 14 provided outside the vacuum chamber 11 passes through the viewing port 16 and is condensed to the photoelectric film 1 by the condensing lens 3 provided on a back surface of the photoelectric film 1. This condensing position is an excitation point 17 of the photoelectric film 1, and the emitted electron beam 5 is used as a probe of the scanning electron microscope 100. At this time, when the photoelectric film 1 is irradiated with continuous light as the excitation light 15, a continuous electron beam 5 is emitted, when the photoelectric film 1 is irradiated with pulsed light, a pulsed electron beam 5 having a pulse width and a pulse period similar to those of the excitation light 15 is emitted. The structure of the electron gun 10 of the embodiment is effective for both of the use conditions of the continuous electron beam and the pulsed electron beam.

As illustrated in FIG. 1, when the condensing lens 3 is provided in the vicinity of the back surface of the photoelectric film 1 serving as an electron emission surface, the excitation light 15 transmitting through the transparent substrate 2 can be condensed with a large numerical aperture of 0.5 or more. A condensing diameter of the excitation light 15 having a wavelength A condensed to the photoelectric film 1 by the condensing lens 3 having the numerical aperture NA is about the same as A/NA. At this time, a size (virtual light source diameter) of an electron emission region of the photoelectric film 1 is about the same as the condensing diameter of the excitation light 15. By activating the NEA on the surface of the photoelectric film 1, a lower end of a conduction band has an energy level higher than a vacuum level, and the electron beam 5 excited from a valence band to the conduction band by the irradiation of the excitation light 15 is efficiently emitted from an inside of the photoelectric film 1 to a vacuum region. In particular, when an active layer of the photoelectric film 1 is p-type GaAs, an effective mass of electrons excited accompanying the light irradiation is as small as 0.067 times the effective mass of electrons in vacuum, and therefore an electron emission angle at the time when the electrons are emitted from the NEA surface to the vacuum region is small, about 10 degrees or less. With the above factors, high luminance characteristics are obtained.

While high luminance can be obtained by the electron source using the photoelectric film 1 formed of p-type GaAs having a high impurity concentration, electron emission characteristics depend on the state of the NEA surface and tend to receive a bad influence of gas molecules. In order to reduce this problem, the vacuum exhaust equipment 13 is connected to each vacuum chamber, and a plurality of differential exhaust structures, in which diaphragm holes (passage holes 7A, 8A) with a diameter of approximately 1 mm or less are provided in a partition wall of each vacuum chamber to allow the electron beam 5 to pass therethrough, are provided between the electron gun chamber 11 and a sample chamber 18. Regarding a configuration of the sample chamber 18, FIG. 4 can be referred to.

However, in a structure of an axisymmetric electron microscope 100r in which the electron gun chamber 11 and the sample chamber 18 are arranged in a straight line as in a structure of an electron gun 10r according to the comparative embodiment illustrated in FIG. 2, a gas flows from a vacuum chamber close to the sample chamber 18 where the degree of vacuum is relatively low into a vacuum chamber (for example, the electron gun chamber 11) close to the electron gun 10r where the degree of vacuum is high, and a part of gas molecules passing through differential exhaust diaphragms 8 and 7r reach a surface of the photoelectric film 1 that is an electron source. By reducing diameters (for example, the diameter) of diaphragm holes of the differential exhaust diaphragms 8 and 7r, the amount of gas molecules reaching the surface can be reduced. But in the case of the configuration in FIG. 2, it is difficult to completely eliminate the bad influence caused by the inflow of the gas molecules into the electron gun chamber 11.

That is, a passage hole 7Ar provided in the first differential exhaust diaphragm 7r and the passage hole 8A provided in the second differential exhaust diaphragm 8 are arranged in a straight line, and the passage hole 7Ar and the passage hole 8A are both arranged at axisymmetric positions.

As illustrated in FIG. 15, in the embodiment, the passage hole 7A provided in the first differential exhaust diaphragm 7 of the scanning electron microscope 100 is provided at a non-axisymmetric position with respect to a central axis 7ac of the first differential exhaust diaphragm 7. On the other hand, the passage hole 8A provided in the second differential exhaust diaphragm 8 is provided at an axisymmetric position with respect to a central axis 8ac of the second differential exhaust diaphragm 8.

In contrast, in the comparative embodiment, the passage hole 7Ar provided in the first differential exhaust diaphragm 7r of the scanning electron microscope 100r is provided at an axisymmetric position with respect to the central axis 7ac of the first differential exhaust diaphragm 7. Further, the passage hole 8A provided in the second differential exhaust diaphragm 8 is provided at an axisymmetric position with respect to the central axis 8ac of the second differential exhaust diaphragm 8.

The above problem can be avoided by controlling non-axisymmetrically the trajectory of the electron beam 5 emitted from the photoelectric film 1. In the embodiment, a configuration is described in which an applied voltage 19 of the photoelectric film 1 is V₀ (<0 V), an applied voltage 20 of the anode electrode 6 is ground potential (0 V), and energy of the electron beam 5 passing through the anode electrode 6 is |eV₀| where e is the elementary charge. However, voltage values of the applied voltages 19 and 20 of respective electrodes are not limited to the above values. The anode electrode 6 may be implemented as a multi-stage anode electrode including a first anode electrode for controlling an electric field intensity in the vicinity of the photoelectric film 1, a second anode electrode for accelerating after passing through the first anode electrode, and the like, and different voltages can be applied thereto.

When the applied voltages 19 and 20 of the photoelectric film 1 and the anode electrode 6 are V₀ (<0 V) and 0 V, respectively, a lens electric field causing a convex lens action 21 in the vicinity of the photoelectric film 1 and a concave lens action 22 in the vicinity of the anode electrode 6 is generated as illustrated in FIG. 3. Since the photoelectric film 1 is a planar electron source, any point on the photoelectric film 1 can be the excitation point 17. When the excitation light 15 is condensed and irradiated such that the excitation point 17 on the photoelectric film 1 is off an axis of the anode electrode 6, the electron beam 5 emitted from the photoelectric film 1 is deflected so as to be away from an axis (central axis) 12 of the anode electrode 6 by the concave lens action 22 after being focused by the convex lens action 21 as illustrated in FIGS. 1 and 3. A position of the excitation point 17 on the photoelectric film 1 is adjusted so that the electron beam 5 passes through the first differential exhaust diaphragm 7 having the passage hole 7A at a non-axisymmetric position. A deflection angle of the electron beam 5 by the concave lens action 22 formed in the vicinity of the anode electrode 6 is defined as θ0. In a case where the anode electrode 6 is at the ground potential (0 V), when the excitation point 17 is fixed, the deflection angle θ₀ does not change even if the applied voltage 19 (V₀) of the photoelectric film 1 is changed. This is because, in accordance with the laws of electron optics, a central trajectory of the electron beam 5 is preserved when each electrode voltage is changed to be n times the original voltage. An off-axis amount (di) of the excitation point 17 is a distance between the position of the excitation point 17 on the photoelectric film 1 and a position of the axis 12 of the anode electrode 6.

The electron beam 5 deflected by the concave lens action 22 formed in the vicinity of the anode electrode 6 is passed through the first differential exhaust diaphragm 7 having the passage hole 7A at a non-axisymmetric position. The second differential exhaust diaphragm 8 provided directly below the first differential exhaust diaphragm 7 has the passage hole 8A at an axisymmetric position. In the sample chamber 18, an exhaust device (exhaust pump) is configured such that a pressure range around a sample 23 can be set to, for example, tens of Pa to hundreds of Pa. A gas flows from a vacuum chamber side of the sample chamber 18 having a relatively low degree of vacuum into a vacuum chamber (for example, the electron gun chamber 11) close to the electron gun 10 having a higher degree of vacuum.

As illustrated in FIGS. 1 and 4, the deflector 9 is provided between the first differential exhaust diaphragm 7 and the second differential exhaust diaphragm 8. By the deflector 9 (9A and 9B: see FIG. 4), the electron beam 5 passing through the passage hole 7A provided at a non-axisymmetric position is returned back and passes through the passage hole 8A of the second differential exhaust diaphragm 8. With such a structure of the electron gun 10, that is, with a configuration in which the passage hole 7A is provided at a non-axisymmetric position and the passage hole 7A and the passage hole 8A are not provided at positions in a straight line, the gas molecules flying linearly from the sample chamber 18 side to the upper side through the passage hole 8A are blocked by the first differential exhaust diaphragm 7 and do not reach the NEA surface of the photoelectric film 1. On the other hand, by deflection control of the deflector 9, a central portion of the electron beam 5, which is large in current density, is conveyed to the sample 23 without being shielded. Therefore, the electron beam 5 emitted from the photoelectric film 1 can be used as a probe electron beam of the electron microscope 100 without impairing a high luminance characteristic that is a feature of the NEA surface. The probe electron beam 5 that can be used in this manner has higher current stability than in the configuration of the comparative embodiment (see FIG. 2), and gas molecules do not reach the NEA surface of the photoelectric film 1, so that the life of the NEA surface of the photoelectric film 1 can be lengthened. Since a frequency of surface activation treatment for regenerating the NEA surface of the photoelectric film 1 can be reduced as the life of the NEA surface of the photoelectric film 1 is lengthened, a downtime of the electron microscope 100 can be reduced.

The multi-stage deflector 9 (9A and 9B: see FIG. 4) used for trajectory control for returning the electron beam 5, which passes through the first differential exhaust diaphragm 7 having the passage hole 7A at a non-axisymmetric position, may adopt either an electrostatic type (electric field type) or an electromagnetic type (magnetic field type) In particular, when the photoelectric film 1 whose active layer is p-type GaAs is used, it is necessary to bake out the electron gun 10 at a high temperature of 200° C. or higher at the time of vacuum start-up in order to produce extreme high vacuum around the photoelectric film 1. Therefore, it is preferable that components mounted in the electron gun chamber 11 have heat resistance of 200° C. or higher, and are formed of a member that emits less gas in an environment of extreme high vacuum.

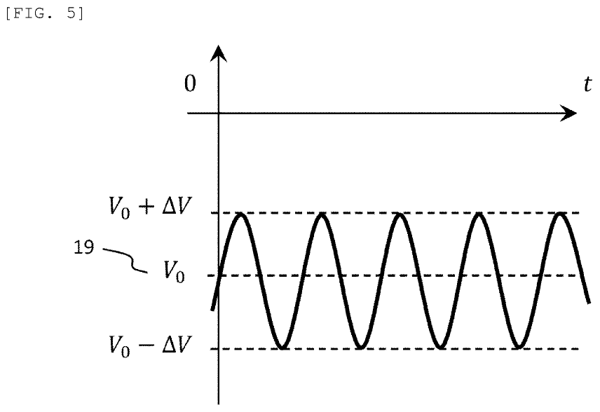

When subjecting the electron beam 5 to deflection control, a deflection chromatic aberration in which a deflection amount depends on the energy of the electron beam 5 is a problem. A bad influence of the deflection chromatic aberration tends to become apparent particularly under irradiation conditions in which irradiation energy of the electron beam 5 is low. In order to use an advantage that energy spread of the electron beam 5 emitted from the NEA surface is small, it is preferable to perform the deflection control such that the chromatic aberration associated with the deflection control is not apparent. In minimizing the bad influence caused by the non-symmetry in the deflection control, a method of controlling the alignment of the electron beam 5 by subjecting the cathode voltage 19 (V₀), which is applied to the photoelectric film 1, to variation over time (see FIG. 5) is effective.

Next, an adjustment method for obtaining optimum alignment conditions based on the configuration of the electron microscope illustrated in FIG. 4 will be described below. FIG. 5 is a graph illustrating variation over time of a cathode voltage according to the first embodiment.

It is considered to minimize the deflection chromatic aberration at a focal point 33 of an electron lens 32 closest to the photoelectric film 1. In the embodiment, a case will be described where the electron lens 32 closest to the photoelectric film 1 is provided with an electrostatic einzel lens. The sample 23 is scanned with the electron beam 5 in a state of being focused by an objective lens 34 at a final stage, and signal electrons 35 generated at each point are detected by a detector 36 to obtain an SEM image. In a case where the cathode voltage 19 (V₀) as a center is varied over time at an appropriate voltage amplitude ΔV (see FIG. 5) when an alignment condition of the deflector 9 is the optimum alignment condition under such SEM observation conditions, a state of image blur of the observed SEM image changes at a fixed period, and states of in-focus and defocus are repeated. On the other hand, when the alignment condition of the deflector 9 is not the optimum condition, image shake in one direction is observed in addition to the variation over time of image blur. A cause of the image shake is that the electron beams 5 having different irradiation energy reach different portions on the sample 23 due to variation in the cathode voltage 19 (V₀). An amplitude of the image shake depends on partial deflection conditions of the electron gun 10, and a condition for minimizing the amplitude of the image shake corresponds to the optimum alignment condition of the deflector 9. The voltage amplitude ΔV of the cathode voltage 19 (V₀) in the variation over time is determined such that the image shake can be recognized with an appropriate amount of blur on the SEM image when the alignment adjustment is performed, and an appropriate voltage amplitude ΔV is set within a range of 10% or less of an absolute value |V₀| of the cathode voltage 19 (V₀).

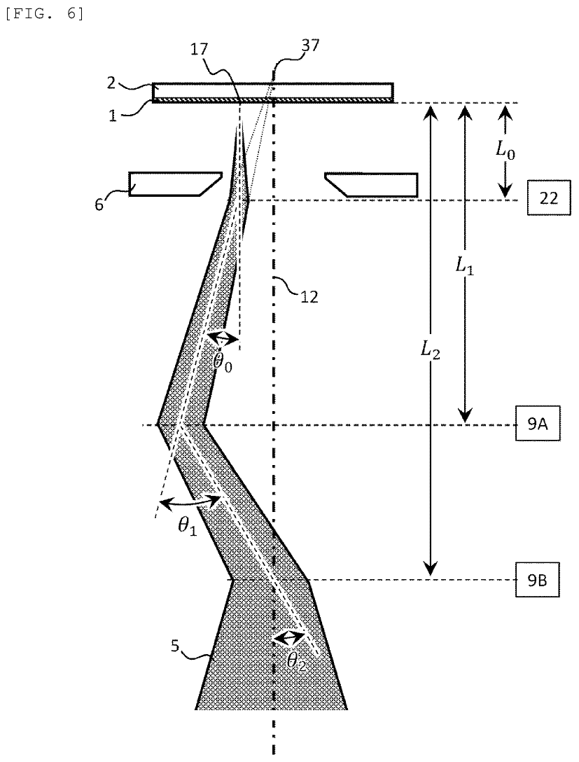

FIG. 6 is a diagram schematically illustrating an electron beam control method according to the first embodiment.

As illustrated in FIG. 6, a deflection angle of the electron beam 5 caused by the concave lens action 22 formed between the photoelectric film 1 and the anode electrode 6 is defined as θ₀, a deflection angle of the electron beam 5 caused by the deflector 9A close to the electron source (photoelectric film 1), which is mounted between the first differential exhaust diaphragm 7 having the passage hole 7A at a non-axisymmetric position and the second differential exhaust diaphragm 8 having the passage hole 8A at an axisymmetric position, is defined as θ₁, and a deflection angle of the electron beam 5 caused by the deflector 9B close to the sample 23 is defined as θ₂. With a virtual light source position 37 of the electron beam 5 as a reference, a distance to a deflection fulcrum by the concave lens action 22 formed between the photoelectric film 1 and the anode electrode 6 is defined as L₀, a distance to a deflection fulcrum of the electron beam 5 by the deflector 9A close to the electron source (photoelectric film 1), which is mounted between the first differential exhaust diaphragm 7 having the passage hole 7A at a non-axisymmetric position and the second differential exhaust diaphragm 8 having the passage hole 8A at an axisymmetric position is defined as L₁, and a distance to a deflection fulcrum of the electron beam 5 by the deflector 9B close to the sample 23 is defined as L₂. At this time, a condition for minimizing an aberration caused by the deflection corresponds to the condition for minimizing the image shake of the SEM image when the cathode voltage 19 is varied over time. When an electrostatic deflector is used for the deflector 9A and the deflector 9B, the following relational expression (formula 1) is established under the condition for minimizing the image shake of the SEM image.

$${L}_{0} {θ}_{0} + {L}_{1} {θ}_{1} + {L}_{2} {θ}_{2} = 0 \qquad ( formula 1 )$$

If the above alignment adjustment is performed in the electron lens 32 closest to the photoelectric film 1, subsequent alignment adjustment is performed in the same manner as an adjustment method used in an electron microscope in the related art, so that desired irradiation performance can be obtained.

The control thereof is executed by the controller 24 that is a control device. The control device 24 varies the cathode voltage applied to the photoelectric film 1 over time, and controls a deflection signal of the deflector 9 for the electron beam 5 in order to adjust the image shake caused by the variation over time. The above-described alignment adjustment of the electron beam 5 in which the cathode voltage 19 (V₀) is varied over time is for minimizing the bad influence of the chromatic aberration caused by a deflection system, and is not essential control. In particular, under a condition that the energy of the electron beam 5 when passing through the deflector 9A and the deflector 9B is large, it is not necessary to perform the above-described control, and the above-described bad influence is sufficiently reduced on the sample 23 by magnification control of the electron optical system. Even under a condition that the energy of the electron beam 5 when passing through the deflector 9A and the deflector 9B is small, the above control is not necessary in a case where the electron beam is used under an observation condition in which the bad influence caused by the deflection system is not apparent, such as observation at a low magnification.

In an ideal configuration of the electron gun 10, the electron beam 5 may be controlled to be deflected in a direction in which the electron beam passage hole 7A non-axisymmetric as viewed from the optical axis is provided, and it is sufficient to provide a multi-stage deflector 9 capable of generating a dipole field. In a minimum configuration, a two-stage deflector (9A, 9B) may be provided. However, actually, a situation may occur in which a desired alignment condition cannot be obtained in a two-stage dipole field due to a non-axisymmetric bad influence of a fringe field, a leakage magnetic field, a ground magnetic field or the like on the path of the electron beam 5. In particular, when the applied voltage 19 (V₀) of the photoelectric film 1 changes, it is assumed that the non-axisymmetric bad influence varies between a condition in which |V₀| is small (a condition in which the irradiation energy of the electron beam is small) and a condition in which |V₀| is large (a condition in which the irradiation energy of the electron beam is large). In order to obtain the optimum alignment condition in consideration of this situation, the deflector 9 can be implemented by a multi-pole electromagnetic pole having good symmetry so as to generate a multi-pole field such as a quadrupole field, a hexapole field, or an octopole field, whereby sufficient correction freedom for the bad influence caused by the non-symmetry can be obtained.

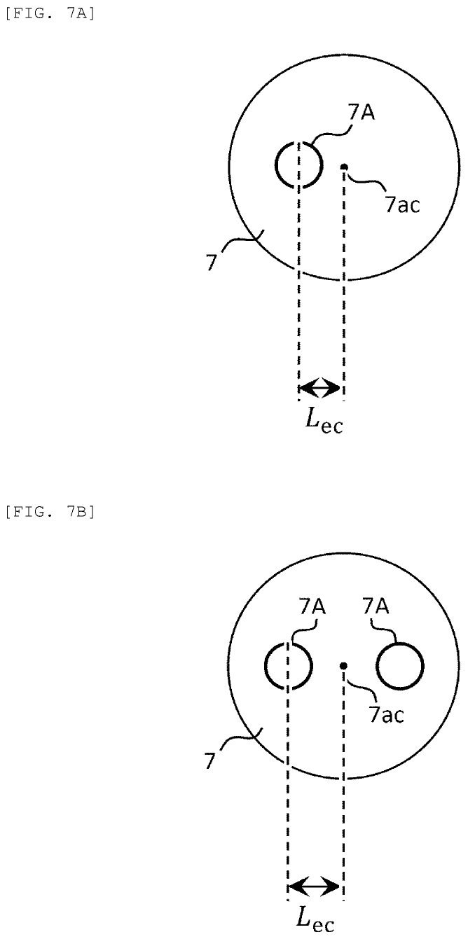

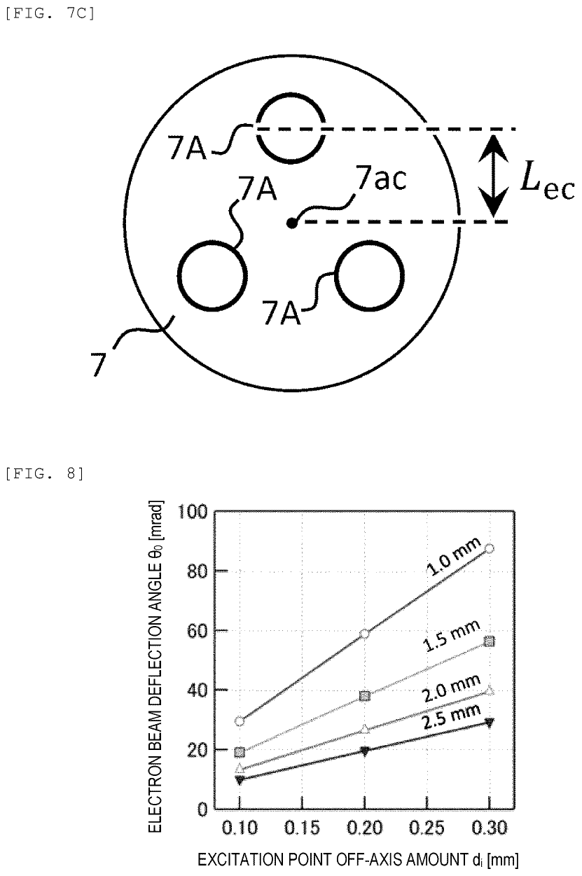

Next, a detailed structure of the first differential exhaust diaphragm 7 having the electron beam passage hole 7A at a non-axisymmetric position, which is placed directly below the photoelectric film 1, will be described below. FIG. 7A is a diagram illustrating a first configuration example of the first differential exhaust diaphragm according to the first embodiment. FIG. 7B is a diagram illustrating a second configuration example of the first differential exhaust diaphragm according to the first embodiment. FIG. 7C is a diagram illustrating a third configuration example of the first differential exhaust diaphragm according to the first embodiment. FIG. 8 is a graph illustrating a relationship between an off-axis amount of the excitation point and a deflection angle of the electron beam according to the first embodiment.

A simplest configuration of the first differential exhaust diaphragm 7 is a configuration in which a single diaphragm hole (passage hole) 7A is provided non-axisymmetrically and a central portion at the central axis 7ac of the first differential exhaust diaphragm 7 is blocked (FIG. 7A). An off-axis eccentricity amount Lec of the diaphragm hole 7A depends on an inter-electrode distance between the photoelectric film 1 and the anode electrode 6, an opening diameter of the anode electrode 6, the off-axis amount di of the excitation point 17, a distance Lapt between the anode electrode 6 and a mounting position of the off-axis diaphragm 7A, and the like. Therefore, trajectory calculation of the electron beam 5 is performed in advance in consideration of the electrode structure inside the electron gun 10, and it is possible to determine the mounting position of the first differential exhaust diaphragm 7 having the passage hole 7A at a non-axisymmetric position, an aperture diameter, the off-axis eccentricity amount Lec, and the off-axis amount di of the excitation point on the photoelectric film. A plurality of first differential exhaust diaphragms 7 having the passage hole 7A at a non-axisymmetric position may be arranged in a diaphragm surface shape.

FIG. 7B illustrates a configuration example in which two off-axis diaphragm holes (passage holes) 7A are provided non-axisymmetrically. FIG. 7C illustrates a configuration example in which three diaphragm holes (passage holes) 7A are provided non-axisymmetrically. In FIGS. 7A to 7C, the passage hole 7A provided non-axisymmetrically is a circular hole, and the shape of the diaphragm hole is not limited to a circular shape as long as necessary differential exhaust performance can be obtained, and the passage hole may be a rectangular or elliptical passage hole.

FIG. 8 illustrates calculation results of the dependence of the deflection angle θ₀ by the concave lens action 22 on the off-axis amount (di) of the excitation point 17 when the distance between the photoelectric film 1 and the anode electrode 6 is set to 1 mm, 1.5 mm, 2 mm, and 2.5 mm for the electrode structure illustrated in FIG. 1 as an example. By increasing the distance Lapt between the anode electrode 6 and the mounting position of the first differential exhaust diaphragm 7 having the passage hole 7A provided non-axisymmetrically, it is possible to increase the off-axis amount (di) of the electron beam 5 on the surface of the first differential exhaust diaphragm 7 having the passage hole 7A provided non-axisymmetrically. On the other hand, since the electron beam 5 spreads in a transverse direction, when an aperture diameter of the passage hole 7A (a diameter of the circular passage hole 7A in plan view) is fixed, it is necessary to pay attention to a fact that the amount of current of the electron beam 5 that can pass through the diaphragm hole is limited. Typically, in the case where a gap distance between the photoelectric film 1 and the anode electrode 6 is 1 mm, when the distance Lapt between the anode electrode 6 and the mounting position of the first differential exhaust diaphragm 7 having the passage hole 7A provided non-axisymmetrically is set to 100 mm, the eccentricity amount Lec of the off-axis diaphragm hole (passage hole) 7A may be set to about 0.45 mm, and the aperture diameter of the passage hole 7A is set to φ 0.6 mm at maximum. Accordingly, the first differential exhaust diaphragm 7 having a blocked central portion and having the diaphragm hole (passage hole) 7A provided non-axisymmetrically can be used as the differential exhaust diaphragm.

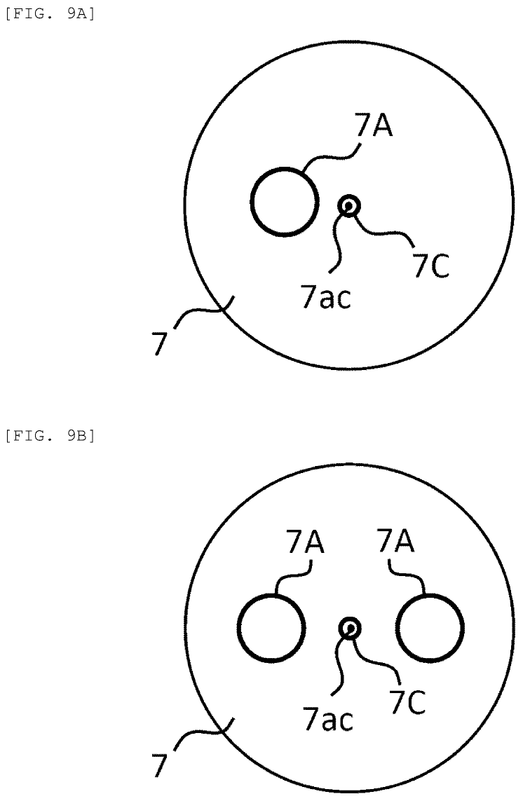

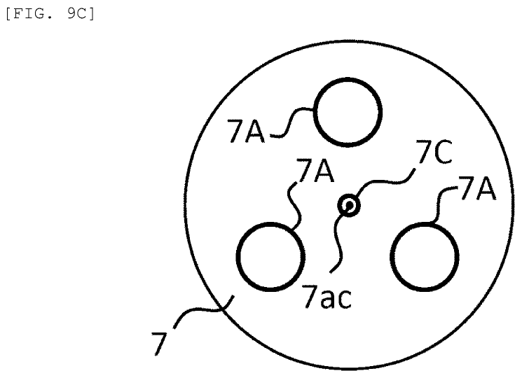

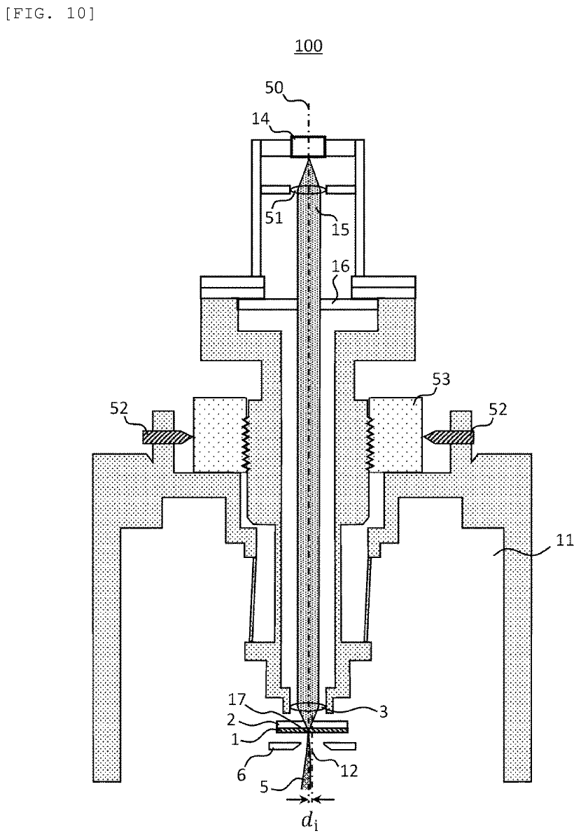

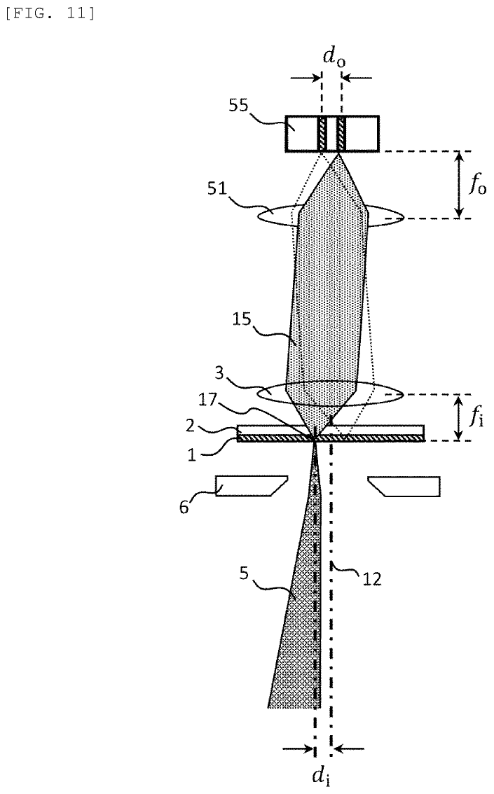

Next, an adjustment method of the electron microscope 100 including the first differential exhaust diaphragm 7 having the diaphragm hole (passage hole) 7A provided non-axisymmetrically will be described. FIG. 9A is a diagram illustrating a fourth configuration example of the first differential exhaust diaphragm according to the first embodiment. FIG. 9B is a diagram illustrating a fifth configuration example of the first differential exhaust diaphragm according to the first embodiment. FIG. 9C is a diagram illustrating a sixth configuration example of the first differential exhaust diaphragm according to the first embodiment.

When the electron beam 5 generated from the NEA surface of the photoelectric film 1 in the structure of the electron gun 10 of the embodiment is to be used as a probe electron beam of the electron microscope 100, in practice, it is easier to use a configuration in which a second adjustment process of controlling the deflection of the electron beam 5 in a direction of the electron beam passage hole (7A) provided non-axisymmetrically in the first differential exhaust diaphragm 7 is performed after a first adjustment process of adjusting the first differential exhaust diaphragm 7 with an axisymmetric configuration first as in the related art. From this point of view, in addition to the electron beam passage hole (7A) provided non-axisymmetrically, it is conceivable that the structure of the first differential exhaust diaphragm is configured to have a passage hole (third through hole, third passage hole) 7C for the electron beam 5 emitted to the central portion (central axis 7ac) under an axisymmetric condition. In the case of using this structure, a linear introducer is used in which a shielding member (also referred to as shielding unit) such as a shielding plate for shielding an electron beam can be retracted in a linear direction from an atmospheric region above or below the first differential exhaust diaphragm 7. In the initial adjustment, the electron beam 5 is conveyed to the sample 23 under an axisymmetric condition, and axial alignment adjustment of the electron lens and alignment adjustment of the electron beam 5 are completed. Thereafter, the electron beam 5 is blocked by the shielding plate so as not to pass through the diaphragm hole 7C at the central portion that is provided axisymmetrically. In order to perform position adjustment such that the condensing lens 3 is in the vicinity of a center of the anode electrode 6, a current measuring unit for the electron beam 5 passing through the diaphragm hole 7C at the central portion may be mounted on a tip end portion of the linear introducer. In this case, the current measuring unit may be used as a shielding member for blocking the diaphragm hole 7C at the central portion.

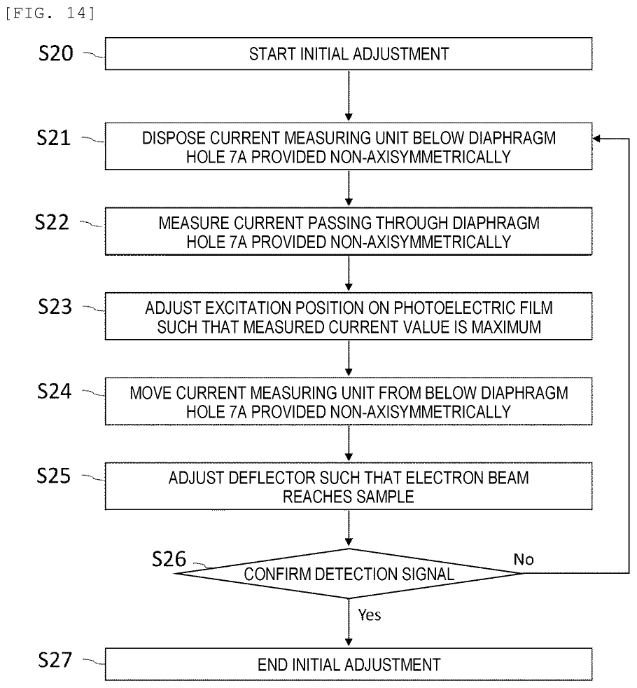

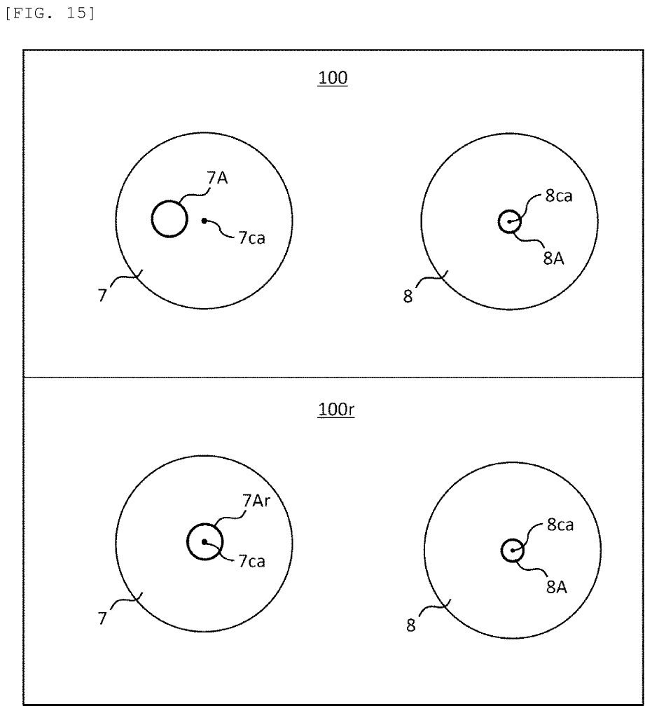

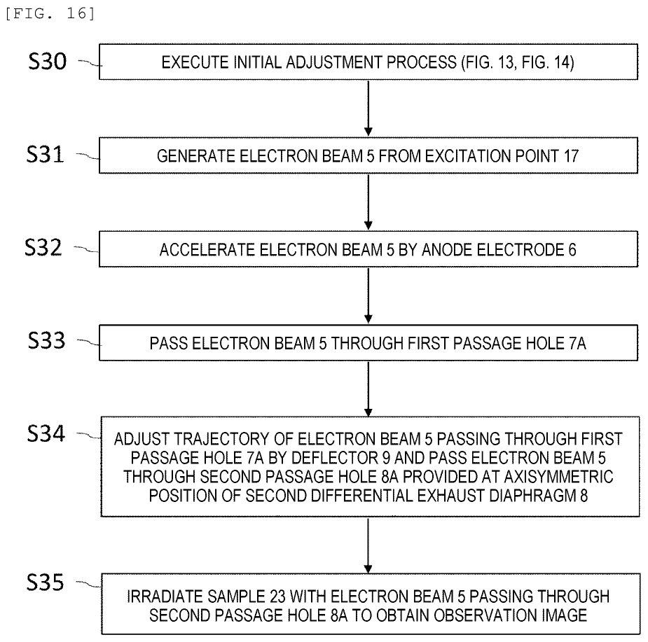

Next, an adjustment procedure of the electron gun 10 including the first differential exhaust diaphragm 7 (FIGS. 9A to 9C) having the diaphragm hole (passage hole) 7A provided non-axisymmetrically and the passage hole 7C will be described with reference to FIG. 13. FIG. 13 is a flowchart illustrating an adjustment procedure of the electron gun according to the first embodiment. FIG. 13 is a flowchart of a control procedure of the electron beam 5 in the initial adjustment in a case where the passage hole 7C for the electron beam 5 is provided axisymmetrically at the central portion in addition to the diaphragm hole (passage hole) 7A provided non-axisymmetrically. Hereinafter, each step (S10 to S17) in FIG. 13 will be described.

(S10): The initial adjustment of the electron gun 10 is started.

(S11): A current measuring unit is provided directly below the central diaphragm hole 7C.

(S12): The photoelectric film 1 is irradiated with the excitation light 15, and a current is measured by the current measuring unit.

(S13): An excitation position on the photoelectric film 1 and light condensing performance for the excitation light 15 are adjusted such that a measurement current is maximum.

(S14): Next, the excitation optical system is adjusted to control the excitation point 17 on the photoelectric film 1 to be off the axis of the anode electrode 6. For the adjustment of the position of the excitation point 17 on the photoelectric film 1, a method described in the second to fourth embodiments described later is applied. An optical path of the excitation optical system is adjusted such that the electron beam 5 reaches an appropriate position at the position of the diaphragm hole (passage hole) 7A provided non-axisymmetrically, compared with a case where the electron beam 5 passes through the passage hole 7C provided axisymmetrically at the central portion.

(S15) The deflector 9 is adjusted such that the electron beam 5 passing through the diaphragm hole (passage hole) 7A provided non-axisymmetrically according to the above procedure reaches the sample 23 placed in the sample chamber 18 of the electron microscope 100.

(S16) Under a condition for passing through the differential exhaust diaphragm provided between the electron gun and the sample chamber, it can be confirmed that the electron beam reaches the sample chamber based on an observation image obtained by the electron microscope using the detector mounted in the sample chamber. When a detection signal is confirmed and the observation image is satisfactory (Yes), the process proceeds to S17. When the detection signal is confirmed and the observation image is not satisfactory (No), the process proceeds to S11, and execution of S11 to S15 is repeated.

(S17): The initial adjustment of the electron gun 10 is ended.

Next, an adjustment procedure of the electron gun 10 including the first differential exhaust diaphragm 7 (FIGS. 7A to 7C) having the diaphragm hole (passage hole) 7A provided non-axisymmetrically (and not having the passage hole 7C) will be described with reference to FIG. 14. FIG. 14 is a flowchart illustrating an adjustment procedure of the electron gun according to the first embodiment. FIG. 14 is a flowchart of the control procedure of the electron beam in the initial adjustment in a case where the diaphragm 7A provided non-axisymmetrically does not have a diaphragm hole in the central portion. Hereinafter, each step (S20 to S27) in FIG. 14 will be described.

(S20): The initial adjustment of the electron gun 10 is started.

(S21): In the case where the diaphragm 7A provided non-axisymmetrically does not have a diaphragm hole in the central portion, since it is not possible to use as a reference the case of passing through the passage hole 7C for the electron beam 5 provided axisymmetrically in the central portion, a current measuring unit is provided directly below the diaphragm hole (passage hole) 7A provided non-axisymmetrically.

(S22): The photoelectric film 1 is irradiated with the excitation light 15, and a current is measured by the current measuring unit.

(S23): An excitation position on the photoelectric film 1 is adjusted such that a measurement current is maximum.

(S24): The current measuring unit is moved from below the diaphragm hole 7A provided non-axisymmetrically.

(S25) The deflector 9 is adjusted such that the electron beam 5 reaches the sample 23 placed in the sample chamber 18 of the electron microscope 100.

(S26) Under a condition for passing through the differential exhaust diaphragm provided between the electron gun and the sample chamber, it can be confirmed that the electron beam reaches the sample chamber based on an observation image obtained by the electron microscope using the detector mounted in the sample chamber. When a detection signal is confirmed and the observation image is satisfactory (Yes), the process proceeds to S27. When the detection signal is confirmed and the observation image is not satisfactory (No), the process proceeds to S21, and execution of S21 to S25 is repeated.

(S27): The initial adjustment of the electron gun 10 is ended.

With the above, the electron beam 5 can be used as a probe electron beam of the electron microscope 100 under the same conditions as those in the case where the first differential exhaust diaphragm 7 has the passage hole 7C for the electron beam 5 provided axisymmetrically substantially at the central portion.

FIG. 16 is a flowchart illustrating an image capturing method of the electron microscope according to the first embodiment. As illustrated in FIG. 16, the image capturing method of the electron microscope includes the following:
0) an initial setting process (see FIG. 13, FIG. 14);
1) a first step of generating the electron beam 5 from the excitation point 17 on the photoelectric film 1;
2) a second step of accelerating the electron beam 5 by the anode electrode 6;
3) a third step of passing the accelerated electron beam 5 through the first passage hole 7A provided at a non-axisymmetric position of the first differential exhaust diaphragm 7;
4) a fourth step of adjusting a trajectory of the electron beam 5 passing through the first passage hole 7A by the deflector 9 and passing the electron beam 5 through the second passage hole 8A provided at an axisymmetric position of the second differential exhaust diaphragm 8; and
5) a fifth step of irradiating the sample 23 with the electron beam 5 passing through the second passage hole 8A to acquire an observation image.

The initial setting process (see FIG. 13, FIG. 14) of the image capturing method of the electron microscope includes the following:
6) a sixth step of disposing a current measuring unit below the first passage hole 7A of the first differential exhaust diaphragm 7 and measuring an emission current of the photoelectric film 1;
7) a seventh step of adjusting a position of the excitation point 17 of the excitation light 15 on the photoelectric film 1 such that a measured emission current is maximum; and
8) an eighth step of adjusting the deflector 9 such that the electron beam 5 passing through the first passage hole 7A reaches the sample 23.

Since the electron gun 10 described above can reduce the bad influence of gas molecules, it is possible to apply an electron source, in which the photoelectric film 1 having an NEA surface is used, to a sample requiring a low vacuum condition such as a biological sample of a cell or an electron microscope including the sample chamber 18 for in-situ environmental control measurement of a reaction between a solid and a gas.

Although the case where the electron gun according to the invention is mounted on a scanning electron microscope has been described in the embodiment, the same electron gun structure can be applied to an electron beam application device such as a transmission electron microscope or a scanning transmission electron microscope.

### Second Embodiment

Next, a second embodiment will be described with reference to FIG. 10. FIG. 10 is a diagram illustrating a schematic configuration example of an excitation optical system and an electron gun according to a second example.

In the embodiment, a configuration is illustrated in which the structure of the electron gun 10 described in the first embodiment is combined with the excitation optical system 4 (see FIG. 1) for condensing and irradiating the excitation light 15 on an active layer of the photoelectric film 1 so that the excitation point 17 on the photoelectric film 1 is off an axis of the anode electrode 6.

The photoelectric film 1 is provided in the vacuum chamber (electron gun chamber) 11 together with the condensing lens 3, and the excitation light 15 emitted from the excitation light source 14 provided outside the vacuum chamber 11 is formed into parallel light by a collimator lens 51, passes through the viewing port 16, and is then condensed to an active layer of the photoelectric film 1 by the condensing lens 3. In order to monitor a condensing state of the excitation light 15 with respect to the photoelectric film 1, the excitation optical system 4 may be configured such that reflected light at the photoelectric film 1 is reflected off an optical axis of the excitation optical system 4 and is condensed to an imaging element by a projection lens. A reference numeral 50 denotes the optical axis of the excitation optical system 4.

When the photoelectric film 1 formed of p-type GaAs is used, an excitation wavelength is preferably 760 nm to 800 nm. When the condensing lens 3 is provided in the vicinity of a back surface of the photoelectric film 1 serving as an electron emission surface, the excitation light 15 transmitting through the transparent substrate 2 can be condensed with a large numerical aperture of 0.5 or more. A condensing diameter of the excitation light having a wavelength λ condensed on the photoelectric film by the condensing lens having the numerical aperture NA is about the same as λ/NA, and an optimum spot diameter is about φ 1 μm in FWHM. At this time, an electron emission region is used as a point source having a size of about φ 1 μm. When using a probe electron beam of the electron microscope 100 as a continuous electron beam, continuous light is emitted, and when using the probe electron beam as a pulsed electron beam, pulsed light is emitted. Any light source can be used as the excitation light source, such as a spatial light output or an optical fiber output, as long as the light source can output light having an intensity necessary for emitting electrons from the photoelectric film 1.

FIG. 10 illustrates a configuration example of the excitation optical system 4 for setting the excitation point 17 off an axis of the anode electrode 6 on the photoelectric film 1. The excitation optical system 4 includes the light source 14, the collimator lens 51, the condensing lens 3, a transparent electrode 2, the photoelectric film 1, and the like. The excitation light 15 emitted from the light source 14 is formed into parallel light by the collimator lens 51, and is condensed and irradiated to the photoelectric film 1 by the condensing lens 3. The condensing lens 3 is fixed in a vacuum chamber of the electron gun 10. The light source 14 and the collimator lens 51 of the excitation optical system 4 are fixed to a flange of the viewing port 16 by using a dedicated holder for fixing an optical element. A position of the entire excitation optical system 4 can be adjusted in any horizontal direction in a horizontal plane by adjusting a four-direction push screw 52 installed at an uppermost portion of the vacuum chamber 11 of the electron gun 10. A distance between the condensing lens 3 and the photoelectric film 1 is adjusted by adjusting a rotation amount of a screw part 53, which is a focal length adjustment mechanism, such that a condensing spot diameter on the photoelectric film 1 is minimized. Regarding details of the mechanism for adjusting the position of the optical system 4 in the electron gun 10 in which the photoelectric film 1 is used, it is preferred to refer to FIG. 3 in Journal of applied physics 103, 064905 (208).

FIG. 10 illustrates a configuration in which the position of the excitation optical system 4 in the horizontal direction is adjusted so that the excitation point 17 is at a position separated from a central axis of the anode electrode 6 by the distance (off-axis amount) di. By using the above-described adjustment mechanism, a position of the condensing lens 3 is adjusted to set the optimum excitation point 17 such that the electron beam 5 passes through the single-hole diaphragm 7A provided non-axisymmetrically as illustrated in FIGS. 7A and 9A. In this manner, the electron beam 5 emitted from the NEA surface of the photoelectric film 1 is used as a probe electron beam of an electron microscope.

### Third Embodiment

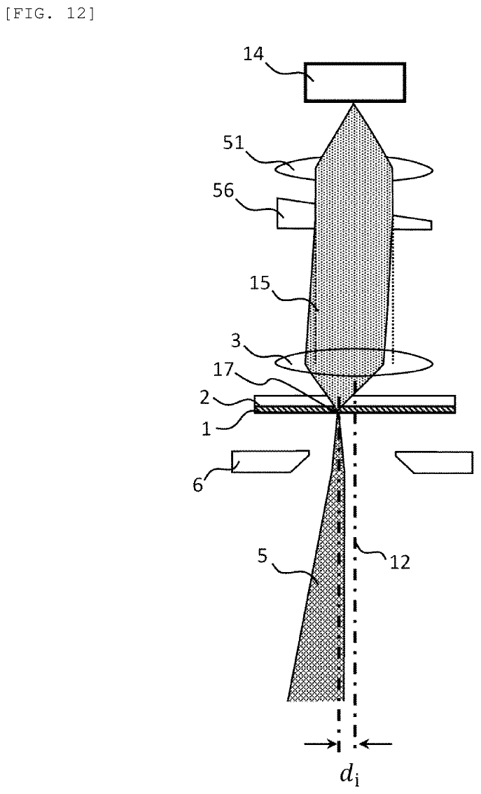

Next, a third embodiment will be described with reference to FIG. 11. FIG. 11 is a diagram schematically illustrating an excitation optical system according to a third embodiment.

In the embodiment, regarding the electron gun structure described in the first embodiment, a configuration is illustrated in which the excitation optical system 4 (see FIG. 1) is fixed and the excitation light 15 can be condensed and irradiated to a plurality of points on the photoelectric film 1, and a plurality of excitation points 17 on the photoelectric film 1 can be used without adjusting an optical path of the excitation optical system 4.

The photoelectric film 1 is provided in the vacuum chamber 11 together with the condensing lens 3, and the excitation light 15 emitted from the excitation light source 14 provided outside the vacuum chamber 11 is formed into parallel light by the collimator lens 51, passes through the viewing port 16, and is then condensed to an active layer of the photoelectric film 1 by the condensing lens 3. In order to monitor a condensing state of the excitation light 15 with respect to the photoelectric film 1, the optical system 4 may be configured such that reflected light at the photoelectric film 1 is reflected off an optical axis of the excitation optical system 4 and is condensed to an imaging element by a projection lens. When the photoelectric film 1 formed of p-type GaAs is used, an excitation wavelength is preferably 760 nm to 800 nm. When the condensing lens 3 is provided in the vicinity of a back surface of the photoelectric film 1 serving as an electron emission surface, the excitation light 15 transmitting through the transparent substrate 2 can be condensed with a large numerical aperture of 0.5 or more. A condensing diameter of the excitation light 15 having a wavelength λ condensed on the photoelectric film 1 by the condensing lens 3 having the numerical aperture NA is about the same as λ/NA, and an optimum spot diameter is about φ 1 μm in FWHM. At this time, an electron emission region is used as a point source having a size of about φ 1 μm. When using a probe electron beam of the electron microscope 100 as a continuous electron beam, continuous light is emitted, and when using the probe electron beam as a pulsed electron beam, pulsed light is emitted.

FIG. 11 illustrates a configuration example of the excitation optical system 4 for setting the excitation point 17 off an axis of the anode electrode 6 on the photoelectric film 1. The excitation optical system 4 includes the light source 14, the collimator lens 51, the condensing lens 3, the transparent electrode 2, the photoelectric film 1, and the like. A case where the first differential exhaust diaphragms 7 having a plurality of passage holes 7A provided non-axisymmetrically as in FIG. 7B, FIG. 7C, FIG. 9B, and FIG. 9C are combined in this configuration will be described.

The excitation light source 14 is implemented by a multi-core fiber 55 and the excitation light source 14 is connected to the multi-core fiber 55. The condensing lens 3 is fixed in the vacuum chamber 11 by a mechanism similar to that illustrated in FIG. 10, and is adjusted in position and fixed in the vicinity of a center of the anode electrode 6 in accordance with the procedure described in the second embodiment. In the case of this mode, an optical path of the excitation light 15 corresponding to the diaphragm hole (passage hole) 7A provided non-axisymmetrically is non-axisymmetric with respect to the excitation optical system 4. The excitation light 15 corresponding to the electron beam 5 passing through the diaphragm hole (passage hole) 7A provided non-axisymmetrically passes through the collimator lens 51 and the condensing lens 3 off respective axes, and is condensed and irradiated to the active layer of the photoelectric film 1. As long as an off-axis amount (di) of a condensing position of the excitation light 15 falls within a maximum angle of view in which light can be condensed by the condensing lens 3, it is possible to obtain condensing characteristics equivalent to those obtained when the optical system 4 is configured having an axisymmetric optical path.

According to the above configuration, by switching the output of the excitation light source 14, the path of the electron beam 5 can be switched and used for the plurality of diaphragms 7A provided non-axisymmetrically. Using a focal length fo of the collimator lens 51 and a focal length fi of the condensing lens 3, the following relational expression (formula 2) is established between an interval do between fiber ends of the multi-core fiber 55 and an interval di of two excitation points 17 for condensing on the photoelectric film 1.

$$di = do \times fi / fo \qquad ( formula 2 )$$

The eccentricity amount Lec of the diaphragm hole (passage hole) 7A provided non-axisymmetrically is calculated based on electron trajectory calculation so that the electron beam emitted from an excitation point positioned at the off-axis amount di passes through the diaphragm hole (passage hole) 7A provided non-axisymmetrically.

At this time, the control system controller 24 is used to control the electron beam 5 in conjunction with the deflector 9, which passes through the diaphragm hole (passage hole) 7A provided non-axisymmetrically, so as to correspond to the output of the excitation light source 14. The control of the output of the excitation light source 14 and a deflection direction in conjunction is switched and used at regular intervals, so that the life of the NEA surface of the photoelectric film 1 can be lengthened and the photoelectric film can be used as a stable electron source over a long period. At this time, the excitation point 17 can be switched at a time interval of about nanoseconds by using a pulsed light source having a minimum pulse width or a minimum pulse interval of about one nanosecond as the excitation light source 14. When an emission intensity of the electron beam 5 varies depending on the excitation point 17 on the photoelectric film 1, an emission current of the photoelectric film 1 can be stabilized and used by changing an irradiation intensity of the excitation light for each excitation point 17.

### Fourth Embodiment

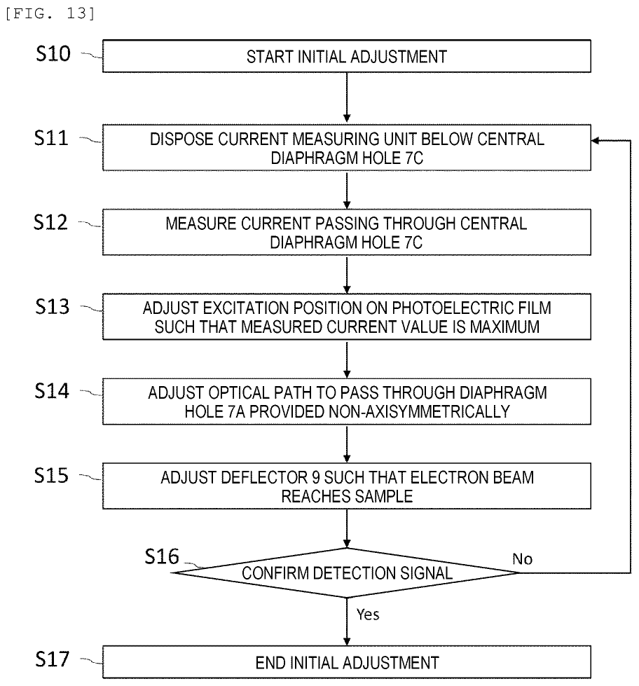

Next, a fourth embodiment will be described with reference to FIG. 12. FIG. 12 is a diagram schematically illustrating an excitation optical system according to a fourth embodiment.

In the embodiment, regarding the electron gun structure described in the first embodiment, a configuration is illustrated in which the excitation light 15 can be condensed and irradiated to a plurality of points on the photoelectric film 1 by using an optical element provided on an optical path of the excitation optical system 4 (see FIG. 1).

The photoelectric film 1 is provided in the vacuum chamber 11 together with the condensing lens 3, and the excitation light 15 emitted from the excitation light source 14 provided outside the vacuum chamber 11 is formed into parallel light by the collimator lens 51, passes through the viewing port 16, and is then condensed to an active layer of the photoelectric film 1 by the condensing lens 3. In order to monitor a condensing state of the excitation light 15 with respect to the photoelectric film 1, the optical system 4 may be configured such that reflected light at the photoelectric film 1 is reflected off an optical axis of the excitation optical system 4 and is condensed to an imaging element by a projection lens. When the photoelectric film 1 formed of p-type GaAs is used, an excitation wavelength is preferably 760 nm to 800 nm. When the condensing lens 3 is provided in the vicinity of a back surface of the photoelectric film 1 serving as an electron emission surface, the excitation light transmitting through the transparent substrate 2 can be condensed with a large numerical aperture of 0.5 or more. A condensing diameter of the excitation light 15 having a wavelength A condensed on the photoelectric film 1 by the condensing lens 3 having the numerical aperture NA is about the same as λ/NA, and an optimum spot diameter is about φ1 μm in FWHM. At this time, an electron emission region is used as a point source having a size of about φ1 μm. When using a probe electron beam of the electron microscope 100 as a continuous electron beam, continuous light is emitted, and when using the probe electron beam as a pulsed electron beam, pulsed light is emitted. Any light source can be used as the excitation light source 14, such as a spatial light output or an optical fiber output, as long as the light source can output light having an intensity necessary for emitting electrons from the photoelectric film 1.

FIG. 12 illustrates a configuration example of the excitation optical system 4 for setting the excitation point 17 off an axis of the anode electrode 6 on the photoelectric film 1. The excitation optical system 4 includes the light source 14, the collimator lens 51, the condensing lens 3, the transparent electrode 2, the photoelectric film 1, and the like. A case where the first differential exhaust diaphragms 7 having a plurality of passage holes 7A provided non-axisymmetrically as in FIG. 7B, FIG. 7C, FIG. 9B, and FIG. 9C are combined in this configuration will be described.

In the embodiment, in order to bend the excitation light 15 off the optical axis of the excitation optical system 14, an optical element (wedge prism) 56 having a wedge-shaped cross section is provided in a region between the collimator lens 51 and the condensing lens 3. Parallel light incident on the wedge prism 56 is refracted as illustrated in FIG. 12 in accordance with Snell's law. An angle at which the parallel light is refracted depends on the material (refractive index) of the wedge prism 56 and an inclination angle of an inclined surface with respect to the optical axis. Therefore, an angle of refraction by the wedge prism 56 is determined based on the off-axis amount di of an excitation point at which the electron beam 5 generated on the NEA surface of the photoelectric film 1 can pass through the diaphragm hole (passage hole) 7A provided non-axisymmetrically in the first differential exhaust diaphragm 7.

Similarly to the third embodiment, the refracted excitation light 15 passes through the condensing lens 3 off an axis thereof and is condensed and irradiated to the active layer of the photoelectric film 1. As long as an off-axis amount (di) of a condensing position of the excitation light 15 falls within a maximum angle of view in which light can be condensed by the condensing lens 3, it is possible to obtain condensing characteristics equivalent to those obtained when the excitation optical system 4 is configured having an axisymmetric optical path.

Similarly to the third embodiment, it is preferable that a horizontal position of the condensing lens 3 is adjusted and fixed in the vicinity of a center of the anode electrode 6. Therefore, first, the optical path is adjusted in a state where the wedge prism 56 is not provided, and the position of the condensing lens 3 is adjusted so as to be located in the vicinity of the center of the anode electrode 6.

By rotating the wedge prism 56 around the optical axis of the excitation optical system 4, the excitation light can be bent in any direction. Therefore, the wedge prism 56 is mounted on a rotation mechanism, and a rotation angle of the wedge prism 56 is controlled such that the electron beam 5 emitted from the excitation point off the axis of the anode electrode can pass through the diaphragm hole (passage hole) 7A provided non-axisymmetrically in the first differential exhaust diaphragm 7, whereby the electron beam 5 emitted by switching the excitation point 17 on the photoelectric film 1 can be used.

At this time, the control system controller 24 is used to control the electron beam 5 in conjunction with the deflector 9, which passes through the diaphragm hole (passage hole) 7A provided non-axisymmetrically, so as to correspond to the rotation angle of the wedge prism 56. The control of the rotation angle of the wedge prism 56 and a corresponding deflection direction in conjunction is switched and used at regular intervals, so that the life of the NEA surface of the photoelectric film 1 can be lengthened and the photoelectric film can be used as a stable electron source over a long period. At this time, the excitation point 17 can be switched at a time interval of about nanoseconds by using a pulsed light source having a minimum pulse width or a minimum pulse interval of about one nanosecond as the excitation light source 14. When an emission intensity of the electron beam 5 varies depending on the excitation point 17 on the photoelectric film 1, an emission current of the photoelectric film 1 can be stabilized and used by changing an irradiation intensity of the excitation light for each excitation point 17.

Although the invention made by the present inventor has been specifically described above based on the embodiments, it is needless to say that the invention is not limited to the above-described embodiments and examples, and various modifications can be made.

### REFERENCE SIGNS LIST

1: photoelectric film
2: transparent substrate
3: condensing lens
4: optical system, excitation optical system
5: electron, electron beam
6: anode electrode
7: first differential exhaust diaphragm
7A: electron beam passage hole (first passage hole) of diaphragm provided non-axisymmetrically
7B: central portion of diaphragm plate
7C: electron beam passage hole (third passage hole) at central portion of diaphragm plate
8: second differential exhaust diaphragm
8A: electron beam passage hole (second passage hole) of diaphragm provided axisymmetrically
9: multi-stage deflector
9A: upper deflector
9B: lower deflector
10: electron gun
11: electron gun chamber
12: axis of anode electrode
13: exhaust system (ion pump, NEG pump)
14: light source, excitation light source
15: excitation light
16: viewing port
17: excitation point
18: sample chamber
19: applied voltage of photoelectric film (cathode voltage)
20: applied voltage of anode electrode
21: convex lens action of electrostatic lens
22: concave lens action of electrostatic lens
23: sample
24: control system (control device, controller)
32: electron lens
33: focal point of electron lens
34: objective lens
35: signal electron
36: detector
37: virtual light source
50: optical axis of excitation optical system
51: collimator lens
52: push screw
53: screw part, focal length adjustment mechanism
55: multi-core fiber 56: wedge prism (optical element having wedged-shaped cross section)

1. An electron microscope comprising:
an excitation light source configured to generate excitation light;
a photocathode including a transparent substrate and a photoelectric film;
a condensing lens configured to condense the excitation light toward the photocathode;
an anode electrode provided facing the photocathode and configured to accelerate an electron beam, the electron beam being generated from an excitation point of the photoelectric film of the photocathode when the excitation light condensed by the condensing lens is incident through the transparent substrate of the photocathode;
a first differential exhaust diaphragm provided close to the photocathode and having a first passage hole provided non-axisymmetrically with respect to an electron optical system;
a second differential exhaust diaphragm provided closer to a sample with respect to the first differential exhaust diaphragm and having a second passage hole provided axisymmetrically with respect to an electron optical system; and
a deflector provided between the first differential exhaust diaphragm and the second differential exhaust diaphragm and configured to adjust a trajectory of the electron beam.

2. The electron microscope according to claim 1, further comprising:
a control device configured to vary a cathode voltage over time that is applied to the photocathode and control a deflection signal of the deflector for the electron beam in order to adjust image shake caused by the variation over time.

3. The electron microscope according to claim 2, wherein
the photoelectric film is a semi-conductor whose surface exhibits negative electron affinity.

4. The electron microscope according to claim 2, further comprising:
an adjustment mechanism configured to adjust a horizontal position of an excitation optical system including the excitation light source, the condensing lens, and the photoelectric film.

5. The electron microscope according to claim 2, wherein
a multi-core fiber is provided, and
the excitation point on the photoelectric film is switched according to an output of the excitation light source connected to the multi-core fiber.

6. The electron microscope according to claim 5, wherein
the control device controls an output of the excitation light source and a deflection direction of the electron beam by the deflector in conjunction with each other.

7. The electron microscope according to claim 2, wherein
the first differential exhaust diaphragm has a third passage hole provided axisymmetrically with respect to the electron optical system.

8. The electron microscope according to claim 7, further comprising:
a shielding unit configured to shield the third passage hole of the first differential exhaust diaphragm.

9. The electron microscope according to claim 8, wherein
the shielding unit includes a current measuring unit.

10. The electron microscope according to claim 2, further comprising:
a sample chamber in which the sample is placed, wherein
a pressure range around the sample is allowed to be set to tens of Pa to hundreds of Pa.

11. An image capturing method of an electron microscope, comprising:
a first step of generating an electron beam from an excitation point on a photoelectric film;
a second step of accelerating the electron beam by an anode electrode;
a third step of passing the accelerated electron beam through a first passage hole provided at a non-axisymmetric position of a first differential exhaust diaphragm;
a fourth step of adjusting a trajectory of the electron beam passing through the first passage hole by a deflector and passing the electron beam through a second passage hole provided at an axisymmetric position of a second differential exhaust diaphragm; and
a fifth step of irradiating a sample with the electron beam after the electron beam passes through the second passage hole to acquire an observation image.

12. The image capturing method of an electron microscope according to claim 11, further comprising:
an initial setting process including
a sixth step of disposing a current measuring unit below the first passage hole of the first differential exhaust diaphragm and measuring an emission current of the photoelectric film,
a seventh step of adjusting a position of the excitation point on the photoelectric film such that a measured emission current is maximum, and
an eighth step of adjusting the deflector such that the electron beam passing through the first passage hole reaches the sample.
